(19) United States
(12) Patent Application Publication
(10) Pub. No.: US 2007/0198904 A1
(43) Pub. Date: Aug. 23, 2007

(54) Error correction processing apparatus and error correction processing method

(75) Inventor: Kenji Yoshida, Akishima-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/585,078

(22) Filed: Oct. 24, 2006

(30) Foreign Application Priority Data
Jan. 31, 2006 (JP) 2006-023615

(51) Int. Cl. H03M 13/00

(52) U.S. Cl. 714/785

(57) ABSTRACT

According to one embodiment, when a digital data row A is error-uncorrectable, error correction is carried out on the basis of an error pattern which can be acquired without using syndromes. When a digital data row B after the error correction is error-correctable, error correction is carried out by generating syndromes with respect to the digital data row B by an EXCLUSIVE-OR operation of syndromes at error bit positions and syndromes calculated from the digital data row A.

### CROSS-REFERENCE TO RELATED APPLICATIONS

This application is based upon and claims the benefit of priority from Japanese Patent Application No. 2006-023615, filed Jan. 31, 2006, the entire contents of which are incorporated herein by reference.

### BACKGROUND

1. Field

One embodiment of the invention relates to improvement in an error correction processing apparatus and an error correction processing method by which error correction processing is applied to a digital data row to which encoding processing for error correction has been applied.

2. Description of the Related Art

As is commonly known, when a digital data row is recorded on an information recording medium such as a hard disk, an optical disk, or the like, the digital data row is recorded after encoding processing for error correction is applied to the digital data row. Then, during reproduction, the original digital data row is restored by applying error correction processing based on an error correcting code to the digital data row read from the information recording medium.

This error correction processing can be achieved such that a syndrome is calculated from the digital data row, and an error position polynomial and an error evaluation polynomial are solved by utilizing the syndrome, and an error pattern is calculated from the solutions thereof, and the digital data row is corrected on the basis of the error pattern.

However, when errors exceeding the maximum correcting capability of the error correcting code are generated in the digital data row read from the information recording medium, error correction is impossible. It can be judged on the basis of the calculated syndrome whether or not errors exceeding the maximum correcting capability of the error correcting code are generated.

By the way, even when errors exceeding the maximum correcting capability are generated in the digital data row read from the information recording medium, when a part of the error pattern is well known, or there is a candidate for an error pattern with high reliability, it is possible to carry out error correction onto the digital data row on the basis of the error pattern.

Then, when error correction processing is carried out on the basis of the error pattern acquired by means other than the means for calculating from a syndrome in this way, in some cases, with respect to the digital data row after the error correction processing, the number of errors included therein is within a range of the correcting capability by the error correcting code, and the status is made to be able to carry out error correction processing by the error correcting code.

In such a case, under the present circumstances, error correction processing is carried out by recalculating a syndrome from the digital data row after error correction processing is carried out on the basis of an error pattern acquired by means other than the means for calculating from a syndrome. Therefore, it takes time to recalculate a syndrome, which impairs speeding-up of error correction processing.

In Jpn. Pat. Appln. KOKAI Publication No. 6-303149, there is disclosed a configuration in which respective syndromes when one-bit errors are generated at respective bit positions in a received code are stored as a table, and two-bit error correction is carried out such that the error bit positions are detected by sequentially determining a three-input exclusive OR of two types of one-bit error syndromes read from the table and a syndrome of a received signal.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 shows one embodiment of the present invention, and is a block diagram shown for explanation of an outline of an HDD;

FIG. 2 is a diagram shown for explanation of one example of a digital data row to which error correction processing in the embodiment is applied;

FIG. 3 is a diagram shown for explanation of one example of a syndrome table used for the error correction processing in the embodiment;

FIG. 4 is a block diagram shown for explanation of one example of a decoding processing unit built in the HDD in the embodiment;

FIG. 5 is a flowchart shown for explanation of part of processing operations of the decoding processing unit in the embodiment; and

FIG. 6 is a flowchart shown for explanation of the rest of the processing operations of the decoding processing unit in the embodiment.

### DETAILED DESCRIPTION

Various embodiments according to the invention will be described hereinafter with reference to the accompanying drawings. In general, according to one embodiment of the invention, when a digital data row A is error-uncorrectable, error correction is carried out on the basis of an error pattern which can be acquired without using syndromes. When a digital data row B after the error correction is error-correctable, error correction is carried out by generating syndromes with respect to the digital data row B by an EXCLUSIVE-OR operation of syndromes at error bit positions and syndromes calculated from the digital data row A.

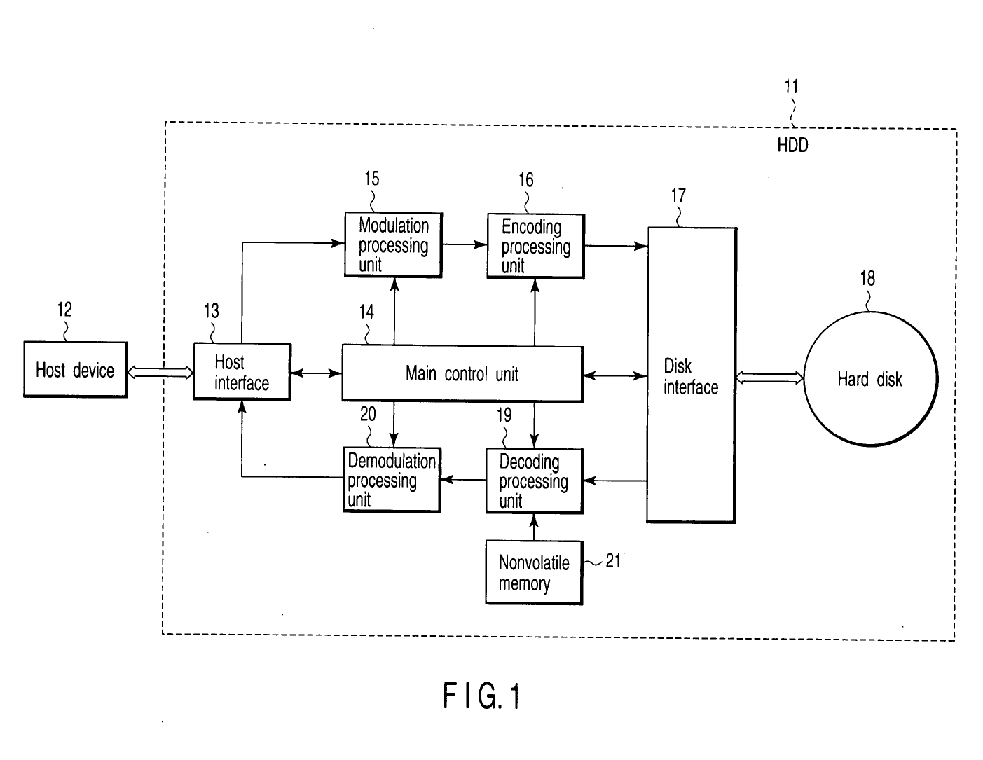

FIG. 1 shows an outline of a hard disk drive (HDD) 11 serving as an information recording/reproducing apparatus which will be described in the embodiment. Namely, this HDD 11 has a host interface 13 for carrying out transmission/reception of information with an external host device 12.

Here, the above-described host device 12 is, for example, a personal computer (PC) or the like. For example, at the time of executing a predetermined application software, the host device 12 executes writing and reading of information by utilizing the HDD 11, and can utilize the HDD 11 as a destination to save information obtained finally.

In this case, the host device 12 issues commands to request writing and reading of information with respect to the HDD 11. These commands are supplied to a main control unit 14 via the host interface 13 to be analyzed. The main control unit 14 has a built-in central processing unit (CPU), and controls overall various operations executed by the HDD 11.

For example, when a write-request command is supplied from the host device 12, the command to request write is supplied to the main control unit 14 via the host interface 13 to be analyzed. In accordance therewith, the main control unit 14 drives a modulation processing unit 15 and an encoding processing unit 16, and controls a hard disk 18 so as to be in a writable state via a disk interface 17.

Further, a digital data row to be written is supplied to the modulation processing unit 15 via the host interface 13. The modulation processing unit 15 applies a compressive modulation processing (for example, modulation processing for not continuing zero for a constant length or more) in a form corresponding to a request of a recording/reproducing system in the HDD 11, such as, for example, a run-length encoding processing, with respect to the input digital data row.

The digital data row to which modulation processing has been applied by the modulation processing unit 15 is supplied to the encoding processing unit 16. The encoding processing unit 16 calculates error correcting code (ECC) parity serving as an error correcting code based on, for example, a Reed-Solomon (RS) code, and adds it to the input digital data row.

Then, the digital data row to which the ECC parity has been added by the encoding processing unit 16 is written into the hard disk 18 via the disk interface 17, which achieves processing for writing the digital data row into the hard disk 18 based on a write request from the host device 12.

Further, when a read-request command is supplied from the host device 12, the read-request command is supplied to the main control unit 14 via the host interface 13 to be analyzed. Therefore, the main control unit 14 drives a decoding processing unit 19 and a demodulation processing unit 20, and controls the hard disk 18 so as to be in a read-state via the disk interface 17.

Then, the digital data row (including the ECC parity) read from the hard disk 18 is supplied to the decoding processing unit 19 via the disk interface 17. The decoding processing unit 19, which will be described in detail later, applies error correction processing based on the ECC parity with respect to the input digital data row.

The digital data row to which error correction processing has been applied by the decoding processing unit 19 is supplied to the demodulation processing unit 20. The demodulation processing unit 20 restores the original digital data row by carrying out demodulation processing onto compressive modulation, such as, for example, run-length encoding processing, to be applied to the input digital data row.

Then, the digital data row to which demodulation processing has been applied by the demodulation processing unit 20 is output to the host device 12 via the host interface 13, which achieves processing for reading the digital data row from the hard disk 18 based on a read request from the host device 12.

Note that a nonvolatile memory 21 is connected to the decoding processing unit 19. The nonvolatile memory 21, which will be described in detail later, has stored therein a table in which, with respect to a digital data row in which one error correcting unit is structured by adding ECC parity, syndromes when one-bit errors are generated in respective bit positions thereof are respectively calculated.

Here, one example of a digital data row in which one error correcting unit is structured by adding ECC parity will be described. For example, a case will be considered in which encoding processing that error corrections to a maximum of 10 areas by an RS code structured on a Galois field GF (2¹⁰) is possible is applied to, for example, user data of 512 bytes (4096 bits given that 1 byte=8 bits).

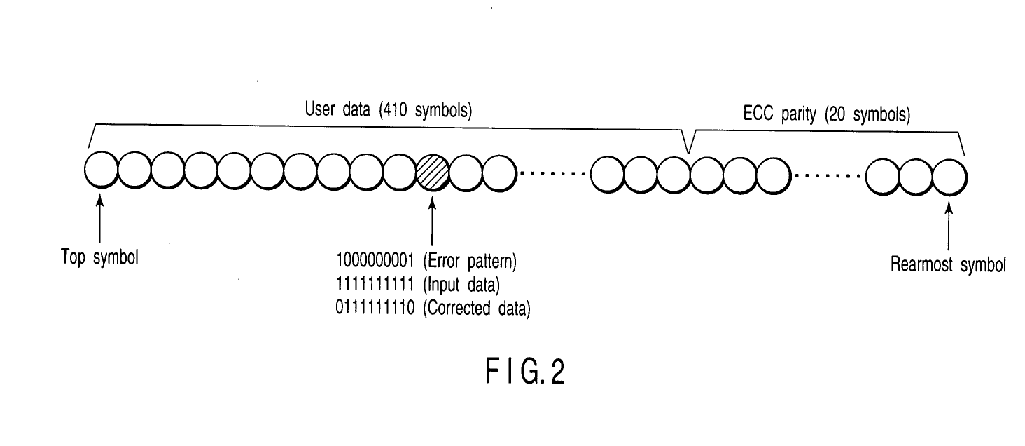

In the case of this example, as shown in FIG. 2, given that one symbol (10 bits) is expressed by one round mark, this is an encoded digital data row of 430 symbols (4300 bits) in which ECC parity of 20 symbols (200 bits) has been added to user data of 410 symbols (4100 bits), and it is possible to correct symbol errors to a maximum of 10.

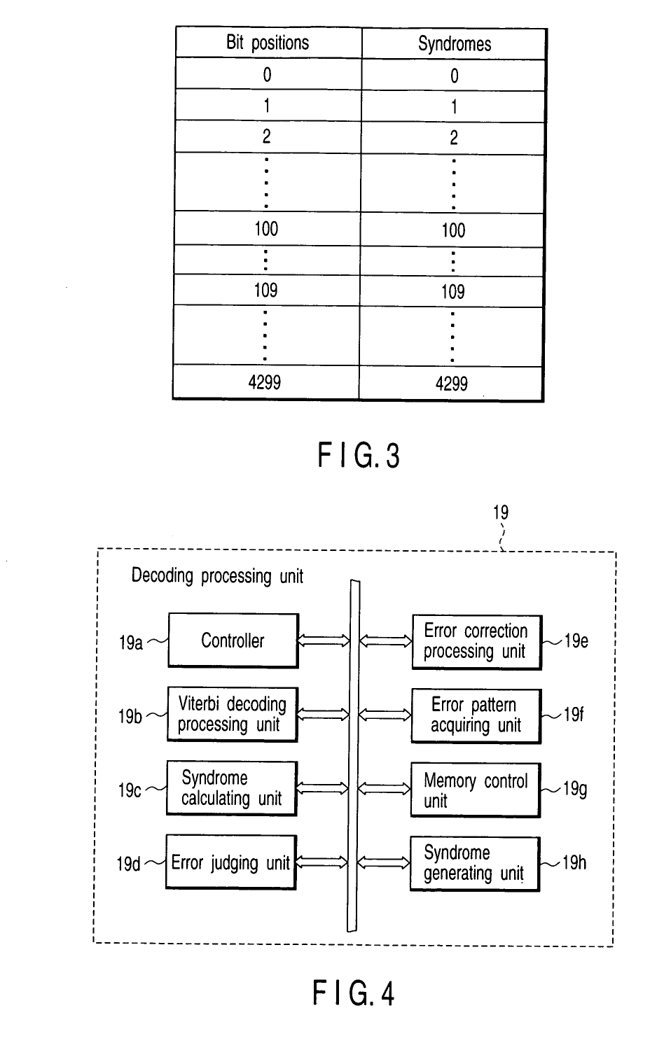

Then, with respect to the digital data row of 4300 bits structuring one error correcting unit shown in FIG. 2, respective syndromes when one-bit errors are respectively generated in the respective bit positions are calculated in advance, and as shown in FIG. 3, those are stored as a syndrome table in the nonvolatile memory 21.

In FIG. 3, with respect to the digital data row of 4300 bits shown in FIG. 2, given that the top bit position of the top symbol thereof is 0, and the rearmost bit position of the rearmost symbol is 4299, the respective bit positions and syndromes calculated so as to correspond to the respective bit positions are stored so as to correspond to one another.

FIG. 4 shows one example of the decoding processing unit 19. Namely, the decoding processing unit 19 can transmit and receive data to and from the main control unit 14, and has a controller 19a for controlling overall various operations executed by the decoding processing unit 19, on the basis of control of the main control unit 14.

Then, the decoding processing unit 19 has a Viterbi decoding processing unit 19b which applies Viterbi decoding processing to an input digital data row, a syndrome calculating unit 19c which calculates syndromes from the digital data row to which Viterbi decoding has been applied, an error judging unit 19d which judges the number of symbol errors from the calculated syndromes, an error correction processing unit 19e which calculates an error pattern on the basis of the calculated syndromes when the number of symbol errors is within a range of the error correcting capability by ECC parity, and applies error correction processing to the input digital data row, and the like.

Further, the decoding processing unit 19 has an error pattern acquiring unit 19f. The error pattern acquiring unit 19f is to acquire the error pattern, for example, when at least a part of an error pattern is well known, or a candidate for an error pattern with high reliability is obtained in process of Viterbi decoding processing, or the like, i.e., when an error pattern with high reliability can be obtained without carrying out calculation by using the syndromes.

Moreover, the decoding processing unit 19 has a memory control unit 19g for acquiring a desired syndrome by making an access to the nonvolatile memory 21, and a syndrome generating unit 19h, which will be described in detail later, for generating a syndrome without carrying out calculation by the syndrome calculating unit 19c by utilizing a syndrome acquired from the nonvolatile memory 21.

By the way, with respect to the digital data row shown in FIG. 2, it is possible to correct symbol errors to a maximum of 10. Therefore, when it becomes clear that there are symbol errors over 10, for example, of 11 from the calculated syndromes, it is impossible to apply error correction processing on the basis of the syndromes. Suppose that the digital data row in which 11 symbol errors are generated is A.

Here, suppose that there is an error symbol at the 11th from the head, and an error pattern with high reliability (for example, 1000000001) is obtained with respect to the error symbol. Then, provided that error correction is applied to the 11th error symbol from the head (for example, 1111111111) by using the error pattern, concretely, provided that an EXCLUSIVE-OR operation of the error pattern (1000000001) and the error symbol (1111111111) is carried out, a correct symbol (0111111110) can be obtained by applying error correction to the 11th error symbol from the head.

Then, by applying error correction to the 11th error symbol from the head in this way, the digital data row A is made to be a digital data row B in which ten symbol errors are generated. Therefore, with respect to the digital data row B, error correction processing by calculating syndromes is possible. However, when syndromes are recalculated with respect to the digital data row B, which takes a processing time, speeding-up of error correction processing deteriorates.

Then, in the present embodiment, an attempt is effectively made to speed up error correction processing by shortening a time required for recalculation of syndromes with respect to the digital data row B. More specifically, when an error pattern which is 1000000001 is obtained in the 11th error symbol from the head of the digital data row shown in FIG. 2, there are errors in bits specified by 1, i.e., the 101st bit and the 110th bit from the head.

Therefore, with reference to the syndrome table shown in FIG. 3, a syndrome 100 corresponding to the 101st bit from the head (bit position 100) and a syndrome 109 corresponding to the 110th bit from the head (bit position 109) are acquired.

Then, by carrying out an EXCLUSIVE-OR operation of the syndromes calculated already with respect to the digital data row A in which 11 symbol errors are generated, the syndrome 100, and the syndrome 109, results of the operation become syndromes of the digital data row B, i.e., syndromes of the digital data row B in which ten symbol errors are generated.

Namely, as compared with the case in which syndromes are calculated by reading all the series of the digital data row B from the beginning, it is possible to easily obtain syndromes of the digital data row B in an extremely short time.

Thereafter, an error position polynomial and an error evaluation polynomial are solved by utilizing the obtained syndromes, and an error pattern is calculated from the solutions thereof, thereby making it possible to carry out error correction onto the digital data row B on the basis of the error pattern. Therefore, it is possible to effectively accelerate speeding-up of error correction processing by shortening a time required for recalculation of syndromes.

Note that, when error correction onto the digital data row B cannot be carried out properly by using the obtained syndromes, this means that the error pattern used for correcting the 11th error symbol from the head of the digital data row A previously is not correct. In this case, when there is a candidate for another error pattern with respect to the 11th error symbol from the head of the digital data row A, the digital data row B is determined by correcting the 11th error symbol from the head again by using it, and in the same way as described above, it is possible to carry out error correction by generating syndromes in a short time.

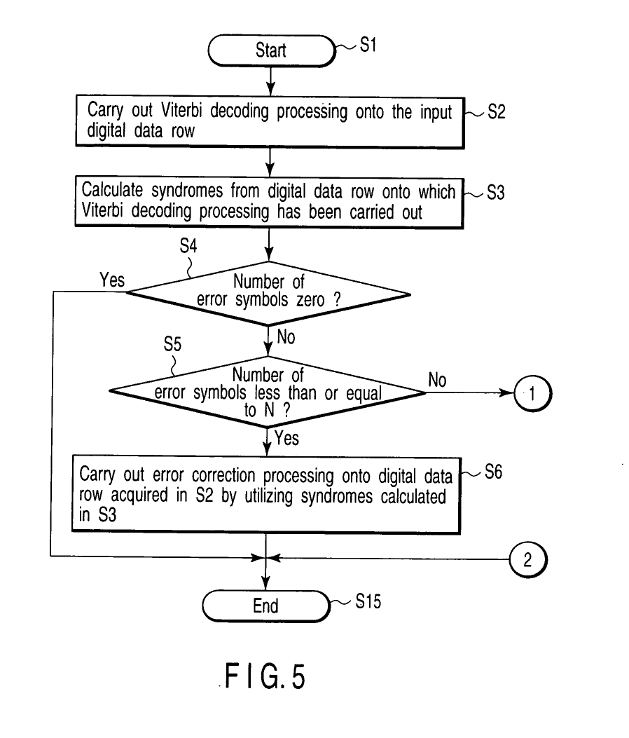

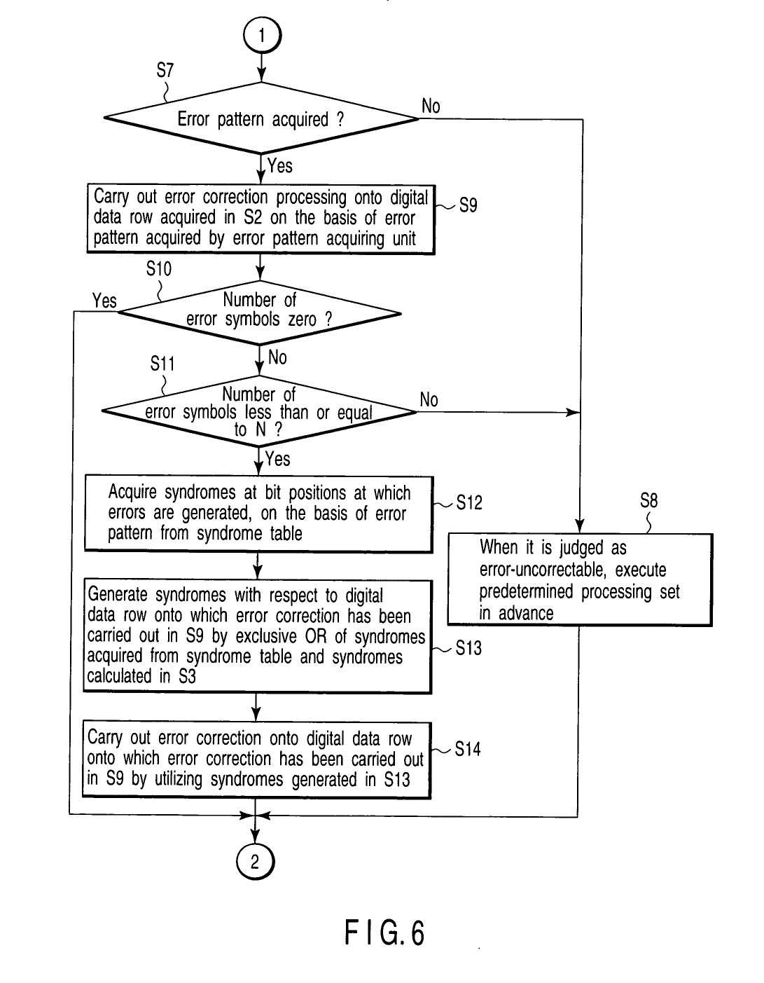

FIGS. 5 and 6 show flowcharts in which processing operations of the decoding processing unit 19 described above are sorted out. The processing operations are started (block S1) due to the digital data row read from the hard disk 18 being inputted to the decoding processing unit 19.

Then, in block S2, the controller 19a makes the Viterbi decoding processing unit 19 execute Viterbi decoding processing onto the input digital data row. Thereafter, in block S3, the controller 19a makes the syndrome calculating unit 19c calculate syndromes with respect to the digital data row onto which the Viterbi decoding processing has been carried out.

Then, in block S4, the controller 19a makes the error judging unit 19d judge whether the number of error symbols is zero or not from the calculated syndromes, and when it is judged that the number of error symbols is zero (YES), the processing is terminated (block S15), and the digital data row from which the ECC parity has been eliminated is outputted to the demodulation processing unit 20 at the subsequent stage.

Further, when it is judged that the number of error symbols is not zero (NO) in block S4, the controller 19a makes the error judging unit 19d judge whether or not the number of error symbols is less than or equal to a maximum correctable number N in block 5.

Then, when it is judged that the number of error symbols is less than or equal to the maximum correctable number N (YES), in block S6, the controller 19a makes the error correction processing unit 19e calculate an error pattern on the basis of the calculated syndromes calculated in block S3, and apply error correction processing to the digital data row onto which the Viterbi decoding processing has been carried out in block S2, on the basis of the error pattern, and the processing is terminated (block S15).

Further, when it is judged that the number of error symbols is over the maximum correctable number N in block S5 (NO), the controller 19a makes the error pattern acquiring unit 19f judge whether or not an error pattern with high reliability is acquired with respect to any error symbol in block S7.

Then, when it is judged that an error pattern has not been acquired (NO), in block S8, the controller 19a judges as error-uncorrectable, and in that case, after predetermined countermeasure processing set in advance is executed, the processing is terminated (block S15).

Further, when it is judged that an error pattern has been acquired (YES) in block S7, the controller 19a makes the error correction processing unit 19e execute error correction processing onto the digital data row onto which the Viterbi decoding processing has been carried out in block S2, on the basis of the error pattern acquired by the error pattern acquiring unit 19f in block S9.

Thereafter, in block S10, the controller 19a judges whether or not the number of error symbols in the digital data row is made zero as a result of the error correction processing in block S9, and when it is judged that the number of error symbols is zero (YES), the processing is terminated (block S15), and the digital data row from which the ECC parity has been eliminated is output to the demodulation processing unit 20 at the subsequent stage.

Further, when it is judged that the number of error symbols is not zero (NO) in block S10, the controller 19a judges whether or not the number of error symbols is less than or equal to the maximum correctable number N in block S11.

Then, when it is judged that the number of error symbols is over the maximum correctable number N (NO), the controller 19a judges as error-uncorrectable in block S8, and in that case, after predetermined countermeasure processing set in advance is executed, the processing is terminated (block S15).

Then, when it is judged that the number of error symbols is less than or equal to the maximum correctable number N (YES) in block S11, the controller 19a makes the memory control unit 19g acquire syndromes at bit positions at which errors have been generated from the syndrome table in the nonvolatile memory 21 on the basis of the error pattern acquired by the error pattern acquiring unit 19f in block S12.

Thereafter, in block S13, the controller 19a makes the syndrome generating unit 19h generate syndromes with respect to the digital data row onto which error correction has been carried out in block S9 by carrying out an EXCLUSIVE-OR operation of syndromes at error bit positions acquired in block S12, and the syndromes calculated in block S3.

Then, in block S14, the controller 19a makes the error correction processing unit 19e calculate an error pattern on the basis of the syndromes generated in block S13, and apply error correction processing to the digital data row onto which error correction processing has been carried out in block S9, on the basis of the error pattern, and the processing is terminated (block S15).

In accordance with the embodiment described above, when the digital data row A has symbol errors exceeding the maximum correcting capability by an error correcting code thereof, and an error pattern with respect to one error symbol is well known, or can be acquired with high reliability, error correction is carried out onto the digital data row A on the basis of the error pattern.

Then, when the number of error symbols in the digital data row B after error correction is less than or equal to the maximum correctable number, syndromes with respect to the digital data row B are generated by carrying out an EXCLUSIVE-OR operation of syndromes at error bit positions acquired from the syndrome table, and syndromes calculated from the digital data row A, and error correction processing onto the digital data row B is carried out on the basis of the syndromes.

Namely, syndromes with respect to the digital data row B can be generated by simple arithmetic processing for merely determining an exclusive OR of syndromes at error bit positions acquired from the syndrome table, and syndromes calculated already from the digital data row A. Therefore, a time required for recalculation of the syndromes with respect to the digital data row B can be extremely shortened, which makes it possible to effectively accelerate speeding-up of error correction processing.

Further, in the embodiment described above, as shown in FIG. 2, the case has been described in which an error pattern can be obtained with respect to an 11th error symbol from the head. However, when error patterns can be respectively acquired for a plurality of error symbols, or an error pattern can be acquired astride a plurality of continuous error symbols, the respective symbols can be respectively corrected on the basis of the error patterns thereof. Moreover, when there is a plurality of candidates for an error pattern, it is possible to carry out error correction due to those being simultaneously applied thereto.

Here, in the embodiment described above, the example has been described in which a hard disk (magnetic disk) is used as an information recording medium. However, it goes without saying that, even if an information recording medium is an optical disk such as, for example, a digital versatile disk (DVD) or the like, an attempt can be made to speed up error correction processing by applying the same technique as that described above.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An error correction processing apparatus comprising:
a calculating unit configured to calculate syndromes from a first digital data row encoded on the basis of an error correcting code;
a first judging unit configured to judge whether or not the first digital data row is error-correctable by the error correcting code on the basis of the syndromes calculated by the calculating unit;
a first correcting unit configured to apply error correction processing to the first digital data row on the basis of the syndromes calculated by the calculating unit when it is judged as error-correctable by the first judging unit;
a second correcting unit configured to apply error correction processing to the first digital data row on the basis of an error pattern which can be acquired without using the syndromes calculated by the calculating unit when it is judged as error-uncorrectable by the first judging unit;
a storage unit configured to store syndromes when bit errors are respectively generated at respective bit positions in the first digital data row, so as to be calculated in advance;
a second judging unit configured to judge whether or not a second digital data row to which error correction processing has been applied by the second correcting unit is error-correctable in accordance with the error correcting code;
a generating unit configured to generate syndromes with respect to the second digital data row on the basis of the syndromes calculated by the calculating unit and syndromes read from the storage unit so as to correspond to error bit positions specified by the error pattern used in the second correcting unit, when it is judged as error-correctable by the second judging unit; and
a third correcting unit configured to apply error correction processing to the second digital data row on the basis of the syndromes generated by the generating unit.

2. An error correction processing apparatus according to claim 1, wherein
the generating unit is configured to generate syndromes with respect to the second digital data row by carrying out an operation of an exclusive OR of the syndromes calculated by the calculating unit, and the syndromes read from the storage unit so as to correspond to error bit positions specified by the error pattern used in the second correcting unit.

3. An error correction processing apparatus according to claim 1, wherein
the second correcting unit is configured to apply error correction processing to the first digital data row by using an error pattern of the acquirable part when at least a part of the error pattern with respect to the first digital data row can be acquired.

4. An error correction processing apparatus according to claim 1, wherein
the second correcting unit is configured to apply error correction processing to the first digital data row by using an error pattern which can be acquired in process of acquiring the first digital data row by applying Viterbi decoding processing to data read from a disk-shaped information recording medium.

5. An information reproducing apparatus comprising:
an acquiring unit configured to acquire a first digital data row encoded on the basis of an error correcting code from a disk-shaped information recording medium;
a calculating unit configured to calculate syndromes from the first digital data row acquired by the acquiring unit;
a first judging unit configured to judge whether or not the first digital data row is error-correctable in accordance with the error correcting code on the basis of the syndromes calculated by the calculating unit;
a first correcting unit configured to apply error correction processing to the first digital data row on the basis of the syndromes calculated by the calculating unit when it is judged as error-correctable by the first judging unit;
a second correcting unit configured to apply error correction processing to the first digital data row on the basis of an error pattern which can be acquired without using the syndromes calculated by the calculating unit when it is judged as error-uncorrectable by the first judging unit;
a storage unit configured to store syndromes when bit errors are respectively generated at respective bit positions in the first digital data row, so as to be calculated in advance;
a second judging unit configured to judge whether or not a second digital data row to which error correction processing has been applied by the second correcting unit is error-correctable in accordance with the error correcting code;
a generating unit configured to generate syndromes with respect to the second digital data row on the basis of the syndromes calculated by the calculating unit and syndromes read from the storage unit so as to correspond to error bit positions specified by the error pattern used in the second correcting unit, when it is judged as error-correctable by the second judging unit;
a third correcting unit configured to apply error correction processing to the second digital data row on the basis of the syndromes generated by the generating unit; and
an output unit configured to output an output from the first or third correcting unit externally.

6. An information reproducing apparatus according to claim 5, wherein
the acquiring unit is configured to acquire the first digital data row by applying Viterbi decoding processing to data read from the disk-shaped information recording medium, and
the second correcting unit is configured to apply error correction processing to the first digital data row by using an error pattern which can be acquired in process of the Viterbi decoding processing.

7. An information reproducing apparatus according to claim 5, wherein
the disk-shaped information recording medium is a magnetic disk.

8. An error correction processing method comprising:
a first block of calculating syndromes from a first digital data row encoded on the basis of an error correcting code;
a second block of judging whether or not the first digital data row is error-correctable in accordance with the error correcting code on the basis of the syndromes calculated in the first block;
a third block of applying error correction processing to the first digital data row on the basis of the syndromes calculated in the first block when it is judged as error-correctable in the second block;
a fourth block of applying error correction processing to the first digital data row on the basis of an error pattern which can be acquired without using the syndromes calculated in the first block when it is judged as error-uncorrectable in the second block;
a fifth block of judging whether or not a second digital data row to which error correction processing has been applied in the fourth block is error-correctable in accordance with the error correcting code;
a sixth block of generating syndromes with respect to the second digital data row on the basis of the syndromes calculated in the first block and syndromes which are read so as to correspond to error bit positions specified by the error pattern used in the fourth block from a storage unit in which syndromes when bit errors are respectively generated at respective bit positions in the first digital data row are calculated in advance and are stored, when it is judged as error-correctable in the fifth block; and
a seventh block of applying error correction processing to the second digital data row on the basis of the syndromes generated in the sixth block.

9. An error correction processing method according to claim 8, wherein
the sixth block generates syndromes with respect to the second digital data row by carrying out an operation of an exclusive OR of the syndromes calculated in the first block, and the syndromes read from the storage unit so as to correspond to error bit positions specified by the error pattern used in the fourth block.

10. An error correction processing method according to claim 8, wherein
the fourth block applies error correction processing to the first digital data row by using an error pattern of the acquirable part when at least a part of the error pattern with respect to the first digital data row can be acquired.

11. An error correction processing method according to claim 8, wherein
the fourth block applies error correction processing to the first digital data row by using an error pattern which can be acquired in process of acquiring the first digital data row by applying Viterbi decoding processing to data read from a disk-shaped information recording medium.
